(19) United States
(12) Patent Application Publication
(10) Pub. No.: US 2014/0110543 A1
(43) Pub. Date: Apr. 24, 2014

(54) PHOTOVOLTAIC PANEL SUPPORT SYSTEM

(71) Applicants: SHAHRIAR SHAMLOO ALIABADI, LAGUNA NIGUEL, CA (US); MICHAEL CHRISTOPHER SALVATI, SANTA ANA, CA (US)

(72) Inventors: SHAHRIAR SHAMLOO ALIABADI, LAGUNA NIGUEL, CA (US); MICHAEL CHRISTOPHER SALVATI, SANTA ANA, CA (US)

(21) Appl. No.: 13/974,285

(22) Filed: Aug. 23, 2013

Related U.S. Application Data
(60) Provisional application No. 61/715,842, filed on Oct. 19, 2012.
(60) Provisional application No. 61/728,201, filed on Nov. 19, 2012.

(51) Int. Cl. H01L 31/042

(52) U.S. Cl. CPC H01L 31/0422
USPC 248/201

(57) ABSTRACT

A photovoltaic panel support system is configured to move in at least three directions to accommodate a photovoltaic panel of any size. The photovoltaic panel support system has a first bracket member with a first bracket member slot bored that can be attached to a mount which can move parallel to the first bracket member slot. A second bracket member is attached to the first bracket member. A second bracket member slot is bored into the second bracket and attached to the first bracket member to permit movement in a second direction parallel to the second bracket member slot. A rail is connected to the second bracket member and has an upper extrusion attached to a lower extrusion that has a key slot. The second bracket member is attached to the key slot which permits movement in a third direction parallel to the key slot.

### RELATED APPLICATION

This application claims priority to provisional patent application U.S. Ser. No. 61/700,822 filed on Sep. 13, 2012; provisional patent application U.S. Ser. No. 61/715,842 filed on Oct. 19, 2012; provisional patent application U.S. Ser. No. 61/728,201 filed on Nov. 19, 2012; the entire contents of each of this is herein incorporated by reference.

### BACKGROUND

The embodiments herein relate generally to systems capable of supporting photovoltaic panels. Prior to embodiments of the disclosed invention, making a one size fits all system to accommodate photovoltaic panels had not been attempted. Rather, improvements were of a more deliberate nature focusing on how to make a rigid system that held a single size panel more effective. The prior art includes: U.S. Patent Application 2011/0203637 filed by Patton; U.S. Patent Application 2010/0043781 filed by Jones; U.S. Patent Application 2009/0114269 filed by Fletcher; U.S. Pat. No. 5,199,836 issued to Gogarty; U.S. Patent Application 2006/60237875 filed by Drees; and U.S. Patent Application 2011/0132853.

Patton teaches a method for installing and removing solar panels using channels and elastic couplings. Patton teaches that springs retract to make room for the panel “and then can return to their original shape.” Patton teaches a “latch snap ring” to prevent the panels from decoupling. Jones teaches a method for installing and removing solar panels using a series of sliding latches as opposed to a latch locking system. Fletcher “contemplates” using a “biasing member” such as a spring in order to hold solar panels in place but essentially uses a variation of the technology in Jones by sliding one rigid member into another. In each of these the “original shape” is rigid and determined by a plurality of members rigidly connected. To contrast embodiments of the present invention can adjust position and size in three directions.

Gogarty teaches a t-nut having a lower head and an upper shank where the shank fitting in a narrow portion of a T-Slot. The head and shank are configured to rotate the nut into the slot fixing the shank to the slot. Drees teaches a T-shaped projection on one end of the rod member is received in a T-shaped slot on the moving core element. The rod member is rotatable between a locked position to engage the first end of the rod member with the moving core element and a second unlocked position to disengage the rod member from the moving core element. Drobot teaches a method of installing supports by twisting “T” slot design which firmly locks a support in place. However, using a key system and being able to set a position within that key are different. Embodiments of the present invention offer greater flexibility by permitting multiple locking position within a keyed channel.

### SUMMARY

A photovoltaic panel support system is configured to move in at least three directions to accommodate a photovoltaic panel of any size. The photovoltaic panel support system has a first bracket member comprising a first bracket member parallel portion and a first bracket member perpendicular portion. A first bracket member slot is bored into the first bracket member parallel portion. A first mounting screw is drilled through the first bracket member and a second mounting screw is inserted through the first bracket member slot in order to attach the first bracket member to a mount which can move in a first direction parallel to the first bracket member slot until the first mounting screw is drilled through the first bracket member.

A second bracket member attached to the first bracket member perpendicular portion. The second bracket member further comprises a second bracket member parallel portion and a second bracket member perpendicular portion. A second bracket member slot is bored into the second bracket member perpendicular portion. The first bracket member perpendicular portion is attached through the second bracket member slot which permits movement in a second direction parallel to the second bracket member slot.

A rail is connected to the second bracket member parallel portion; wherein the rail further comprises an upper extrusion which is mechanically coupled to a lower extrusion. The lower extrusion comprises a key slot; wherein the second bracket member parallel portion is attached to the key slot which permits movement in a third direction parallel to the key slot. The rail can be moved in the first direction, the second direction and the third direction in order to accommodate the photovoltaic panel of any size.

In some embodiments, a compression screw is attached through the upper extrusion into the lower extrusion. A compression spring covering the compression screw raises the upper extrusion from the lower extrusion unless the compression screw is tightened which moves the upper extrusion down toward the lower extrusion. The movement of the upper extrusion is permitted in a fourth direction parallel to the compression screw to accommodate a height of the photovoltaic panel.

In some embodiments, a grounding spring is attached to the lower extrusion. A leaf spring is attached to the lower extrusion; wherein placing the photovoltaic panel against the leaf spring scratches a surface on the photovoltaic panel which grounds the photovoltaic panel without a need for wires. A second leaf spring is attached to a second side on the lower extrusion in order to permit both grounding and alignment of a second photovoltaic panel.

In some embodiments, a first speed clip attaches the first bracket member to the second bracket member and is held in place with a first speed clip set screw. A second speed clip attaches the second bracket member to the rail and is held in place with a second speed clip set screw

### BRIEF DESCRIPTION OF THE FIGURES

The detailed description of some embodiments of the invention is made below with reference to the accompanying figures, wherein like numerals represent corresponding parts of the figures.

FIG. 1 is a front perspective view of an embodiment of the invention.

FIG. 2 is a rear perspective view of an embodiment of the invention.

FIG. 3 is an exploded elevation view.

FIG. 4 is a cross-sectional view taken on line 4-4 of FIG. 2.

FIG. 5 is a cross-sectional view similar to FIG. 4 showing the adjustability of the invention.

FIG. 6 is a cross-sectional view taken on line 6-6 of FIG. 4.

FIG. 7 is a cross-sectional view taken on line 7-7 of FIG. 5.

FIG. 8 is a detail perspective view of an embodiment of the invention.

FIG. 9 is an exploded detail elevation view similar to FIG. 3 of the alternate configuration.

### DETAILED DESCRIPTION OF CERTAIN EMBODIMENTS

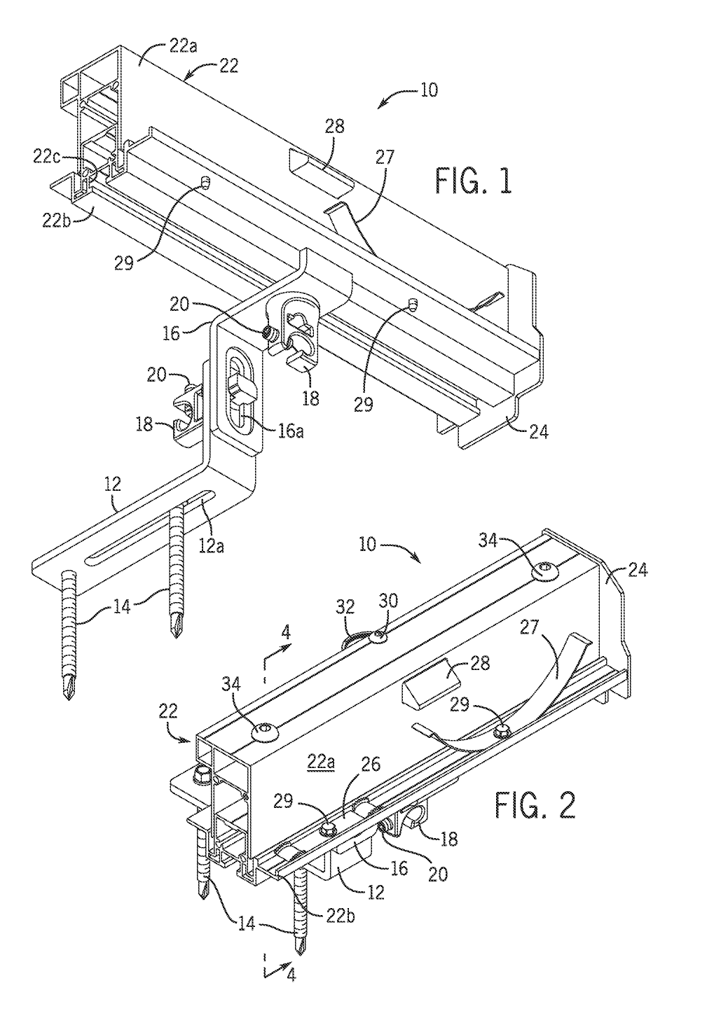

By way of example, and referring to FIG. 1, one embodiment of photovoltaic panel support system 10 comprises first bracket member 12. First bracket member 12 is L-shaped with a parallel portion and a perpendicular portion. The first bracket member parallel portion is bored with bracket member slot 12a. A first mounting screw 14 is drilled through first bracket member 12 and as second mounting screw 14 is inserted through first bracket member slot 12a in order to attach first bracket member 12 to a mount. The second bracket mounting screw 14 can be inserted at any point along first bracket member slot 12a which provides flexibility in installing photovoltaic panel support system 10. The permits and limits motion in a first direction parallel to first bracket member slot 12a.

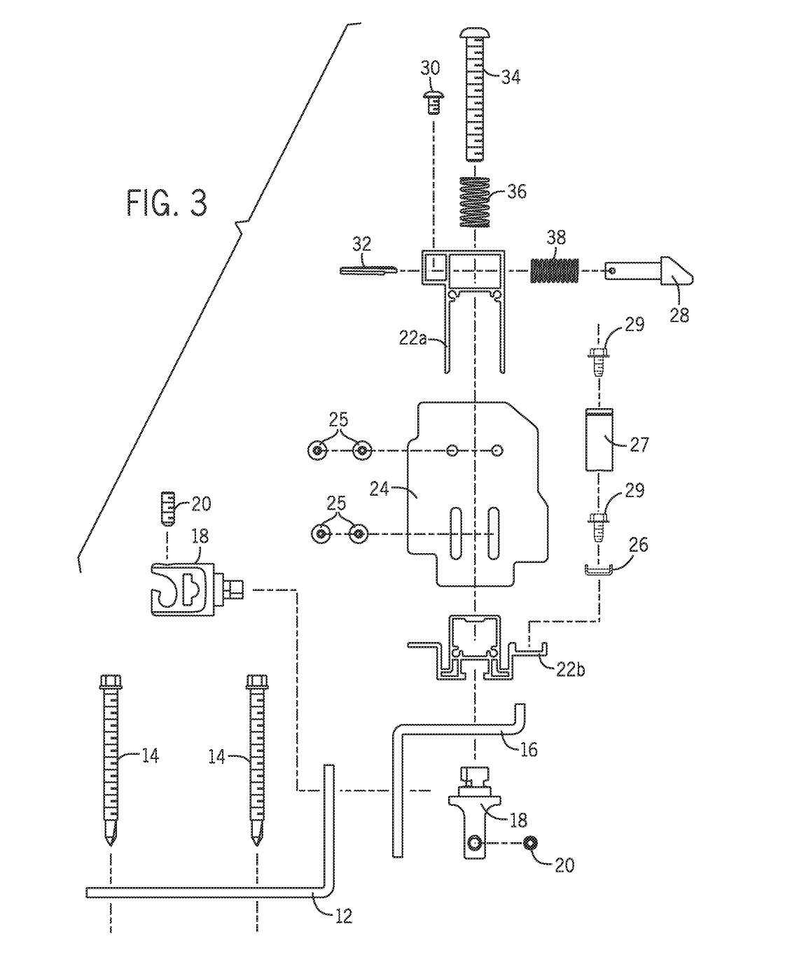

The first bracket member perpendicular portion is immediately adjacent to second bracket member 16. Second bracket member 16 comprises a parallel portion and a perpendicular portion. The second bracket member perpendicular portion is perforated with second bracket member slot 16a. The first bracket member perpendicular portion is perforated with a first bracket member hole. A user can slide first speed clip 18 through the first bracket member hole and into second bracket member slot 16a to mechanically couple the first bracket member perpendicular portion to the second bracket member perpendicular portion. First speed clip 18 can allow a height from ground of the second bracket member perpendicular portion to be fixed before fixing the first speed clip 18 in place by adjusting first speed clip set screw 20. The permits and limits motion in a second direction parallel to second bracket member slot 16a. The second bracket member parallel portion is perforated with a second bracket member hole and connected to a second bracket member lip. Rail 22 can be attached to the second bracket member parallel portion as shown in more detail in FIG. 2 and FIG. 3.

FIG. 2 and FIG. 3 show rail 22 in more detail. Rail 22 comprises upper extrusion 22a which is mechanically coupled to lower extrusion 22b with end cap 24. In some embodiments end cap 24 comprises two upper holes which are attached to upper extrusion 22a with two mounting screws 25. In some embodiments, end cap 24 comprises two slots which are attached to lower extrusion 22b with two mounting screws 25. This construction allows a user to customize the height of rail 22 to accommodate different sizes of photovoltaic panel 40.

Lower extrusion 22b is formed with key slot 22c. A second speed clip can be inserted through the second bracket member hole and into key slot 22c. This allows a user to insert second speed clip 18 through the second bracket member hole. The user can then slide the second speed clip 18 through key slot 22c. Once a desired position for rail 22 is obtained, the user can fix rail 22 in place by tightening second speed clip set screw 22. The permits and limits motion in a third direction parallel to rail 22.

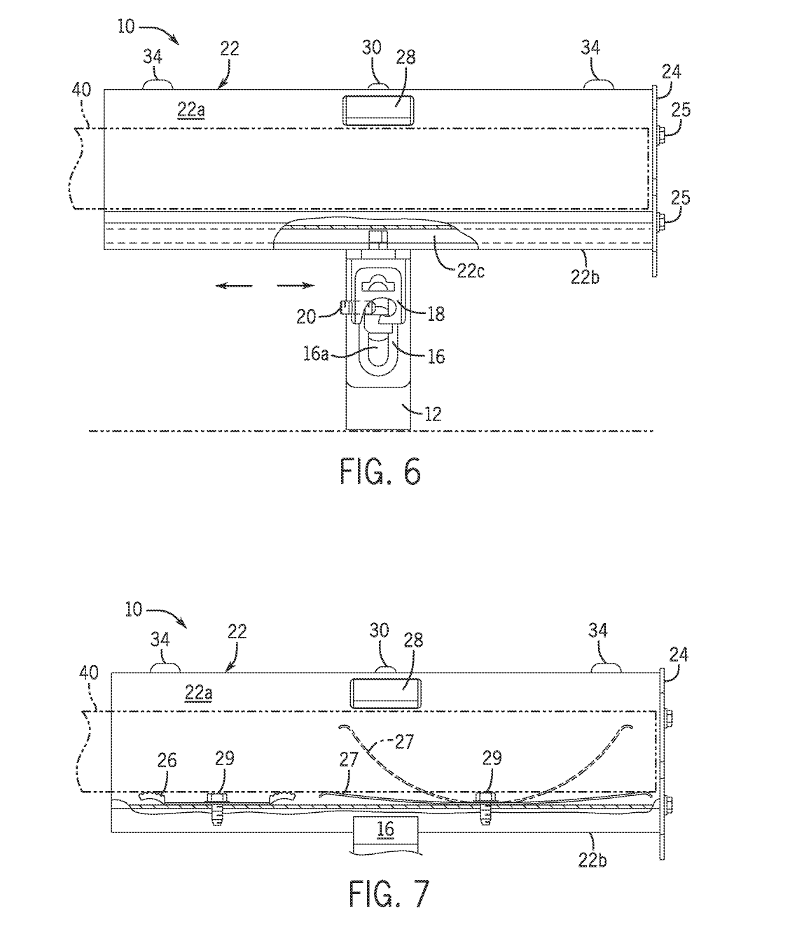

One of the unique features of embodiments of the present invention is the grounding system that does not require external wires as is commonly found in the prior art. Lower extrusion 22b is mechanically coupled to grounding spring 26 with grounding spring mounting screw 29. Lower extrusion 22b is further mechanically coupled to leaf spring 27 with leaf spring mounting screw 29. As shown in FIG. 6 and FIG. 7, when photovoltaic panel 40 is inserted against upper extrusion 22a, leaf spring 27 scratches the surface of photovoltaic panel 40. This scratching permits an errant electrical current in photovoltaic panel 40 to travel through rail 22 into ground with grounding spring 26 without the need for wires.

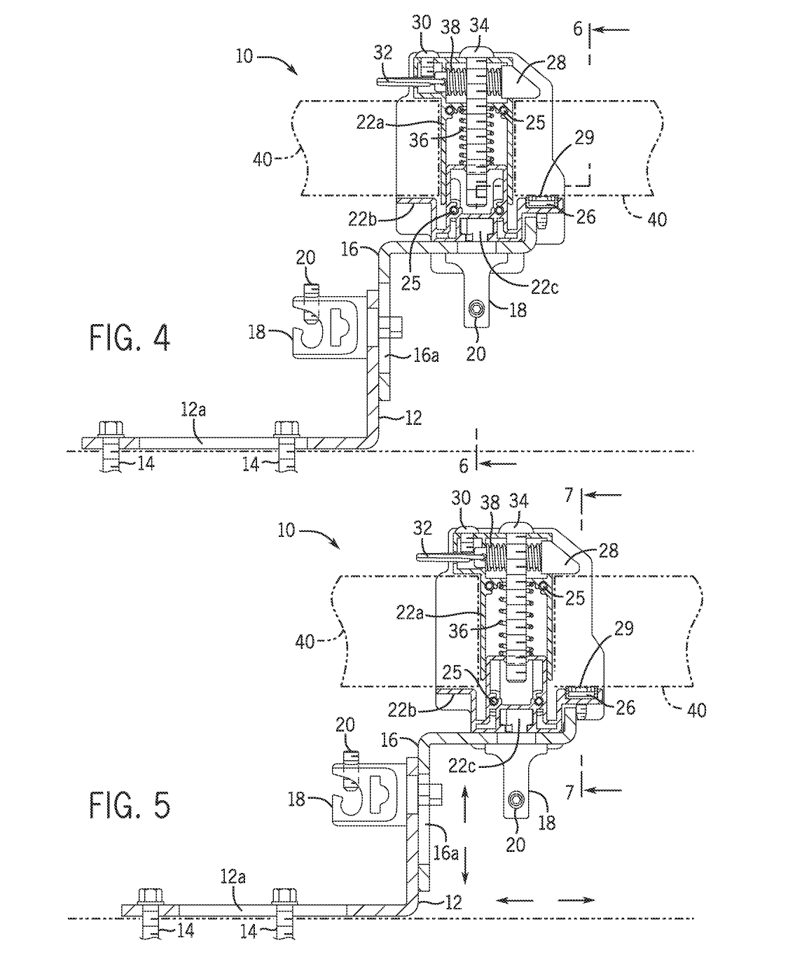

Turning to FIG. 4 and FIG. 5, another unique feature of the present invention is the latch assembly. The latch assembly uses upper extrusion 22a as a housing. Upper extrusion 22a is perforated with a first upper extrusion latch hole through which latch 28 can extend. Latch 28 has a wider portion which can move in and out of upper extrusion 22a and a narrower portion which is surrounded by latching spring and perforated with a latch hole. The narrow portion extends through an opposite end of upper extrusion 22a which has a second upper extrusion latch hole. Motion of latch 28 through the opposite end is interested by latch spring 38 which pushes latch 28 though the first upper extrusion latch hole.

A user can also insert pull ring 32 through the latch hole. This enables the user to pull latch 28 away from leaf spring 27 permitting a user to remove photovoltaic panel 40 from rail 22. This motion can be stopped by inserting latching screw 30 through upper extrusion 22a to prevent inadvertent or unauthorized removal of photovoltaic panel 40 from rail 22.

As noted above, the rapidly customizable nature of photovoltaic panel support system 10 is one feature that can distinguish it from the prior art. One of the customizable features is the ability to adjust height to accommodate different sizes of photovoltaic panel 40. This can be done by inserting compression screw 34 through upper extrusion 22a when it is covered with compression spring 36. Compression screw 34 descends into lower extrusion 22b and can exert sufficient force on compression spring 36 to bring upper extrusion 22a closer to lower extrusion 22b. Likewise, compression screw 34 can be loosened and compression spring 36 will push upper extrusion 22a away from lower extrusion 22b. The permits and limits motion in a fourth direction parallel to compression screw 34.

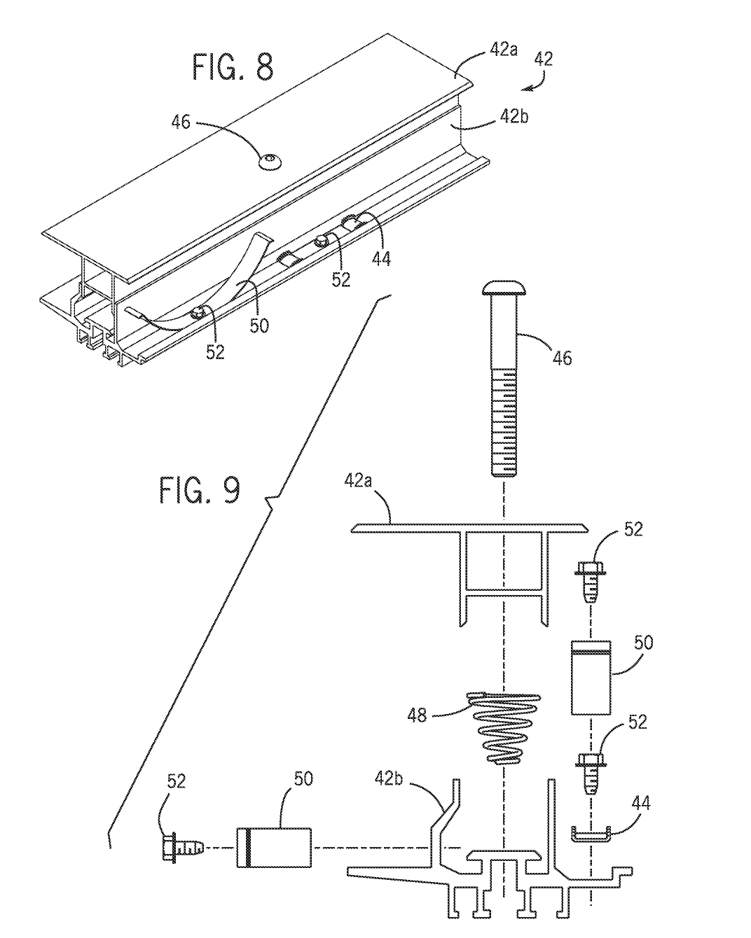

While the latch assembly can be useful, photovoltaic panel support system 10 can be configured to operate without it as shown in FIG. 8 and FIG. 9. Here, rail 42 comprises upper extrusion 42a which is mechanically coupled to lower extrusion 42b without an end cap. Rather, a user inserts compression screw 46 through upper extrusion 42a when it is covered with compression spring 48. Compression screw 46 descends into lower extrusion 42b and can exert sufficient force on compression spring 48 to bring upper extrusion 42a closer to lower extrusion 42b. Likewise, compression screw 46 can be loosened and compression spring 48 will push upper extrusion 42a away from lower extrusion 42b. This construction allows a user to customize the height of rail 42 to accommodate different sizes of photovoltaic panel 40.

Similar to the construction discussed above, lower extrusion 42b is mechanically coupled to grounding spring 44 with grounding spring mounting screw 52. Lower extrusion 42b is further mechanically coupled to leaf spring 50 with leaf spring mounting screw 52. When photovoltaic panel 40 is inserted against upper extrusion 42a, leaf spring 50 scratches the surface of photovoltaic panel 40. This scratching permits an errant electrical current in photovoltaic panel 40 to travel through rail 42 into ground with grounding spring 44 without the need for wires.

In this construction upper extrusion 42a, extends over lower extrusion 42b on both sides, whereas previously is only extended over lower extrusion 42b. Further a second leaf spring 50 can be mechanically coupled to a second side on lower extrusion 42b in order to permit both grounding and alignment of a second photovoltaic panel 40.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. A photovoltaic panel support system configured to move in at least three directions to accommodate a photovoltaic panel of any size; the photovoltaic panel support system comprising;
a first bracket member comprising a first bracket member parallel portion and a first bracket member perpendicular portion;
a first bracket member slot bored into the first bracket member parallel portion; wherein a first mounting screw is drilled through the first bracket member and a second mounting screw is inserted through the first bracket member slot in order to attach the first bracket member to a mount which can move in a first direction parallel to the first bracket member slot until the first mounting screw is drilled through the first bracket member;
a second bracket member attached to the first bracket member perpendicular portion; wherein the second bracket member further comprises a second bracket member parallel portion and a second bracket member perpendicular portion;
a second bracket member slot bored into the second bracket member perpendicular portion; wherein a the first bracket member perpendicular portion is attached through the second bracket member slot which permits movement in a second direction parallel to the second bracket member slot; and
a rail connected to the second bracket member parallel portion; wherein the rail further comprises an upper extrusion which is mechanically coupled to a lower extrusion; the lower extrusion comprises a key slot; wherein the second bracket member parallel portion is attached to the key slot which permits movement in a third direction parallel to the key slot;
wherein the rail can be moved in the first direction, the second direction and the third direction in order to accommodate the photovoltaic panel of any size.

2. The photovoltaic panel support system of claim 1, further comprising:
a grounding spring attached to the lower extrusion;
a leaf spring attached to the lower extrusion
wherein placing the photovoltaic panel against the leaf spring scratches a surface on the photovoltaic panel which grounds the photovoltaic panel without a need for wires.

3. The photovoltaic panel support system of claim 1, further comprising:
a grounding spring attached to the lower extrusion;
a leaf spring attached to the lower extrusion; wherein placing the photovoltaic panel against the leaf spring scratches a surface on the photovoltaic panel which grounds the photovoltaic panel without a need for wires; and
a second leaf spring attached to a second side on the lower extrusion in order to permit both grounding and alignment of a second photovoltaic panel.

4. The photovoltaic panel support system of claim 1, further comprising:
a compression screw attached through the upper extrusion into the lower extrusion;
a compression spring covering the compression screw raises the upper extrusion from the lower extrusion unless the compression screw is tightened which moves the upper extrusion down toward the lower extrusion;
wherein movement of the upper extrusion is permitted in a fourth direction parallel to the compression screw to accommodate a height of the photovoltaic panel.

5. The photovoltaic panel support system of claim 1, wherein
a latch is inserted through the upper extrusion such that the latch can move in and out of the upper extrusion through a first upper extrusion latch hole and a second upper extrusion latch hole;
a latch spring surrounds the latch within the upper extrusion that pushes one end of the latch out of the first upper extrusion latch hole; and
a pull ring is attached to the latch and can be used to pull a portion of the latch into the first upper extrusion latch hole.

6. The photovoltaic panel support system of claim 1, wherein
a latch is inserted through the upper extrusion such that the latch can move in and out of the upper extrusion through a first upper extrusion latch hole and a second upper extrusion latch hole;
a latch spring surrounds the latch within the upper extrusion that pushes one end of the latch out of the first upper extrusion latch hole;
a pull ring is attached to the latch and can be used to pull a portion of the latch into the first upper extrusion latch hole; and
a latching screw inserted through the upper extrusion against the latch to prevent movement of the pull ring.

7. The photovoltaic panel support system of claim 1, wherein a first speed clip attaches the first bracket member to the second bracket member and is held in place with a first speed clip set screw.

8. The photovoltaic panel support system of claim 1, wherein a second speed clip attaches the second bracket member to the rail and is held in place with a second speed clip set screw.
